(19) United States
(12) Patent Application Publication
(10) Pub. No.: US 2026/0251986 A1
(43) Pub. Date: Aug. 27, 2026

(54) DEBRIS CATCHER, ROTATING TARGET EXTREME ULTRAVIOLET (EUV) RADIATION GENERATION SYSTEM, METHOD OF GENERATING EUV RADIATION, METHOD OF INSPECTING PHOTOMASK, METHOD OF MANUFACTURING SEMICONDUCTOR DEVICE

(71) Applicant: Taiwan Semiconductor Manufacturing Company, Ltd., Hsinchu (TW)

(72) Inventors: Hsu-Sheng HUANG, Hsinchu (TW); Hao-Ming CHANG, Hsinchu (TW); Cheng Yuan HSIAO, Hsinchu (TW); Chun-Lang CHEN, Hsinchu (TW); Jhan-Yi LI, Hsinchu (TW)

(73) Assignee: Taiwan Semiconductor Manufacturing Company, Ltd., Hsinchu (TW)

(21) Appl. No.: 19/060,356

(22) Filed: Feb. 21, 2025

(51) Int. Cl. G03F 7/00; H05G 2/00

(52) U.S. Cl. CPC G03F 7/70916; G03F 7/70033; H05G 2/0035; H05G 2/0082

(57) ABSTRACT

A debris catcher includes a concave surface configured to face a target material of a rotating target extreme ultraviolet (EUV) radiation generation system. The rotating target EUV radiation generation system includes a vessel, a crucible, and the catcher. A method of generating EUV radiation includes rotating the crucible, irradiating the target material to generate a plasma emitting the EUV radiation, and directing debris formed with the plasma using the catcher. A method of inspecting a photomask includes directing the EUV radiation to the photomask, capturing one or more images of patterned radiation reflected from the photomask, and processing the one or more images. A method of manufacturing a semiconductor device includes directing the EUV radiation to the photomask, exposing a photoresist layer to patterned radiation reflected from the photomask, developing the photoresist layer, and etching a substrate using the developed photoresist layer as a mask.

### BACKGROUND

In the field of semiconductor device manufacturing, extreme ultraviolet (EUV) radiation is used in connection with photolithography and mask inspection proceses. EUV radiation can be generated by irradiating a target material (e.g., liquid tin) with a laser to form a plasma that emits the EUV radiation. The structure and conditions within a system for generating EUV radiation can affect the stability and integrity of the generated radiation. Degraded EUV radiation can adversely affect lithography and inspection processes that utilize the radiation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic perspective view of a mask inspection tool in accordance with some embodiments.

FIG. 1B is a schematic perspective view of a lithography system in accordance with some embodiments.

FIG. 2 is a schematic cross-sectional view of components of a rotating target EUV radiation generation system in accordance with some embodiments.

FIG. 3 is a schematic perspective view of a crucible in accordance with some embodiments.

FIG. 4 is a schematic plan view of a catcher and a portion of a crucible in accordance with some embodiments.

FIG. 5 is a schematic cross-sectional view of a catcher and a portion of a crucible in accordance with some embodiments.

FIG. 6 is a schematic cross-sectional view of catcher and a portion of a crucible in accordance with some embodiments.

FIG. 7 is a schematic cross-sectional view of a structural interface between a crucible, a shim, a shield, and a frame in accordance with some embodiments.

FIG. 8 is a schematic plan view of a shim in accordance with some embodiments.

FIG. 9 is a schematic cross-sectional view of a portion of a shim in accordance with some embodiments.

FIG. 10 is a schematic cross-sectional view of a portion of a shim in accordance with some embodiments.

FIG. 11 is a schematic cross-sectional view of a portion of a catcher in accordance with some embodiments.

FIG. 12 is a schematic cross-sectional view of an end portion of the catcher shown in FIG. 11 in accordance with some embodiments.

FIG. 13 is a schematic cross-sectional view of a droplet of water exhibiting a contact angle with respect to a material of a catcher in accordance with some embodiments.

FIG. 14 is a schematic cross-sectional view of a catcher and a portion of a crucible in accordance with some embodiments.

FIG. 15 is a schematic view of a computing system according to some embodiments.

FIG. 16 is a flowchart depicting a method of generating extreme ultraviolet (EUV) radiation in accordance with some embodiments.

FIG. 17 is a flowchart depicting a method of inspecting a photomask in accordance with some embodiments.

FIG. 18 is a flowchart depicting a method of manufacturing a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which one or more additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus/device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

The present disclosure relates to improving the stability and integrity of EUV radiation provided by a rotating target EUV radiation generation system. Such EUV radiation generation systems can be used for mask inspection and photolithography. The structure, materials, and operation of the rotating target EUV radiation generation system can play a role in ensuring optimal performance and longevity of the rotating target EUV radiation generation system, as well as optimal performance of associated inspection and lithography processes. Structural elements, materials, and processes associated with the rotating target EUV radiation generation system can influence the stable generation of EUV radiation.

Inspection and lithography tools include optics, which can include one or more components that reflect, transmit, and/or operate on incident light. Examples of such optics include one or more lenses, windows, filters, wedges, prisms, grisms, gratings, transmission fibers, etalons, diffusers, homogenizers, detectors, apertures, axicons, mirrors, specular reflectors, and diffuse reflectors. One or more optics can be used with one or more specific wavelength range(s) such as at the EUV output light wavelength, an irradiation laser wavelength, a wavelength suitable for metrology, or any other specific wavelength.

Herein, the terms mask, photomask, and reticle are used interchangeably. A mask can be a reflective mask used in association with EUV lithography. Such reflective masks can also be inspected using EUV radiation. One embodiment of the mask includes a substrate formed of a suitable material, such as a low thermal expansion material or fused quartz. In some embodiments, the substrate includes TiO₂ doped SiO₂, or other suitable materials with low thermal expansion. In some embodiments, the mask includes multiple reflective layers (ML) deposited on the substrate. In some embodiments, the multiple layers include a plurality of film pairs, such as molybdenum-silicon (Mo/Si) film pairs (e.g., a layer of molybdenum above or below a layer of silicon in each film pair). Alternatively, the multiple layers include molybdenum-beryllium (Mo/Be) film pairs, or other suitable materials that are configurable to reflect the EUV light, in some embodiments. The mask further includes a capping layer, such as ruthenium (Ru), disposed on the ML for protection in some embodiments. In some embodiments, the mask further includes an absorption layer, such as a tantalum boron nitride (TaBN) layer, deposited over the multiple layers. The absorption layer is patterned to define a layer of a semiconductor device in some embodiments. Alternatively, another reflective layer is deposited over the multiple layers and patterned to define a layer of the semiconductor device, thereby forming an EUV phase shift mask.

A lithography system or mask inspection system can include a light projection system configured to direct radiation to the mask. Depending on the nature of the mask and the photolithography process, the radiation can be directed through the mask or reflected from the mask to form a patterned light. In lithography processes, the patterned radiation can be directed to the resist layer to form a pattern therein. In inspection processes, the patterned radiation can be directed to a sensor to collect an image of the radiation. One or more optics can shrink and focus the patterned light onto the resist layer or the sensor.

In some embodiments, the EUV lithography process is used to form a structure in a semiconductor substrate and/or one or more layers formed on the semiconductor substrate. In some embodiments, a semiconductor substrate includes a semiconductor wafer, such as a silicon wafer or other type of wafer. The semiconductor substrate is coated with a photoresist layer sensitive to the EUV light in some embodiments. An EUV lithography system focuses the pattern of EUV radiation on the photoresist layer to cause reactions in the irradiated portions of the layer. A photoresist includes one or more photosensitive materials and can be a positive photoresist or a negative photoresist in some embodiments. After irradiating the photoresist layer, a pattern of openings can be formed in the layer by developing the layer with a developing solution. Developing the positive photoresist can form openings in portions of the layer that have been irradiated. Conversely, developing the negative photoresist can form openings in portions of the layer that have not been not irradiated. Whether a photoresist functions as a negative or positive photoresist can depend on one or more of the composition of the photoresist and the composition of the developing solution. After forming the pattern into one or more layers on or in the semiconductor substrate, the lithography system can repeat the lithography process to form additional structures to form a semiconductor device.

Inspection of masks used in photolithography processes can be conducted to determine whether the masks include defects after initial production, or damage or contamination caused by handling and use of the mask in photolithography processes. Defects, damage, and contamination can adversely affect the performance of the photolithography processes that utilize masks. In some embodiments, masks used in EUV lithography processes are inspected by irradiating the mask with EUV radiation such that mask reflects a pattern of the radiation onto a sensor such as a charge-coupled device (CCD). The sensor can capture one or more images of the patterned radiation. A computing system can be used to process images and determine whether the mask has any defects, damage, or contamination.

Although various embodiments disclosed herein are described with respect to an EUV light generating apparatus used for mask inspection and lithography, other applications of the disclosed embodiments may include other systems that require EUV light without limitation, such as precision metrology systems.

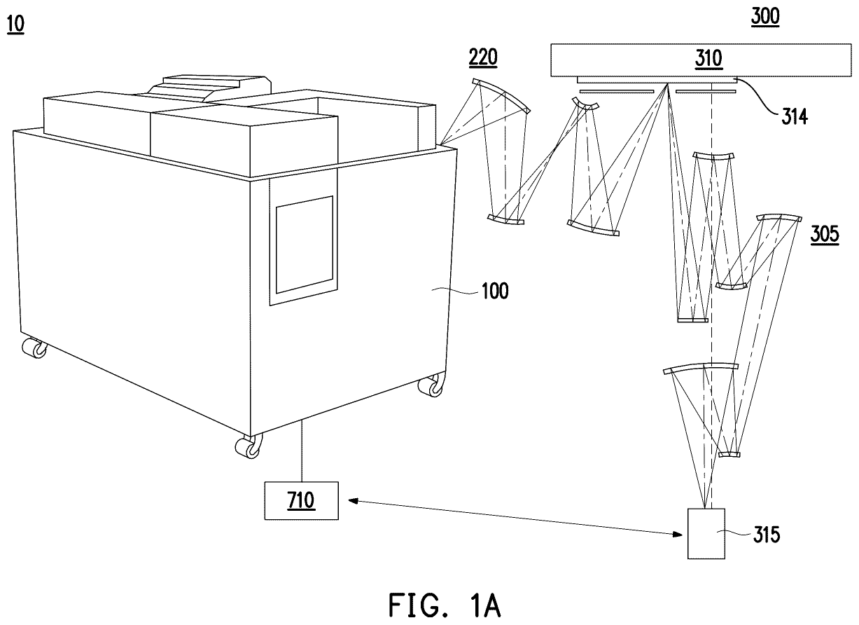

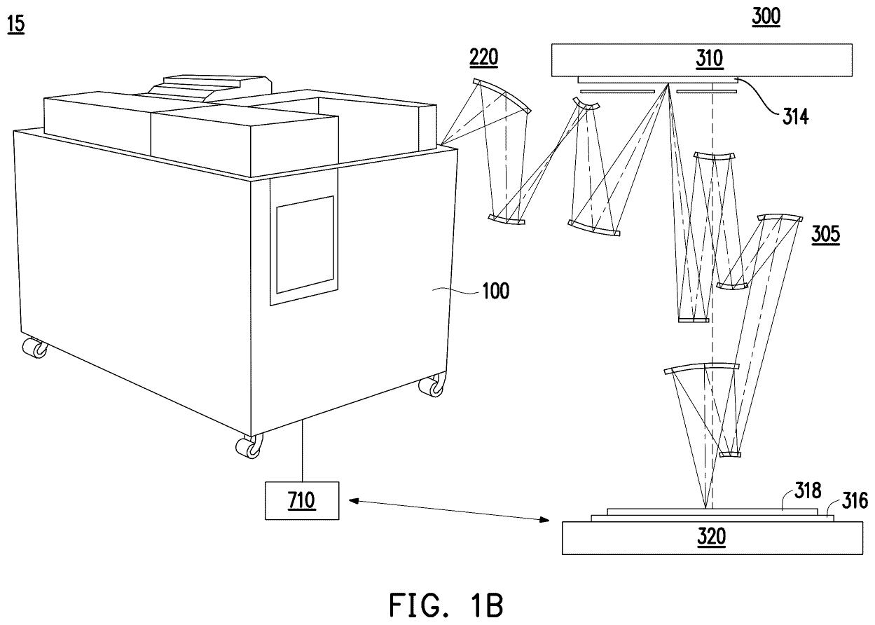

FIG. 1A is a schematic view of an EUV mask inspection system 10 including a rotating target EUV radiation generation system 100 configured to generate EUV light. FIG. 1B is a schematic view of an EUV lithography system 15 including a rotating target EUV radiation generation system 100 configured to generate EUV light. In some embodiments, the rotating target EUV radiation generation system 100 utilizes laser-produced plasma (LPP) to generate the EUV radiation. In some embodiments, the system 100 generates EUV light having a wavelength ranging between about 1 nanometer (nm) and about 100 nm, or a wavelength centered at about 13.5 nm. The system 100 in FIGS. 1A and 1B is coupled to an exposure tool 300 via a coupling mechanism 220. The coupling mechanism 220 can include optics configured to transfer EUV radiation from the rotating target EUV radiation generation system 100 to an exposure tool 300.

In the embodiment illustrated in FIG. 1A, the exposure tool 300 includes a plurality of reflective optic components 305, a mask stage 310, and an inspection sensor 315. In the embodiment illustrated in FIG. 1B, the exposure tool 300 includes a plurality of reflective optic components 305, a mask stage 310, and a wafer stage 320. The EUV radiation from the rotating target EUV radiation generation system 100 is guided within the exposure tool 300 by the reflective optical components 305. The EUV radiation is also directed to the mask 314 secured on the reticle stage 310. In the embodiment illustrated in FIG. 1A, the optical components 305 direct patterned radiation that is reflected from the mask on to the sensor 315. The sensor 315 collects one or more images of the patterned radiation. In some embodiments, a computing system 710 controls the generation of EUV radiation in the rotating target EUV radiation generation system 100 and processes the images collected by the sensor 315 for the presence any defects, damage, or contamination on the mask.

In the embodiment illustrated in FIG. 1B, the pattern of EUV light reflected by the mask 314 is directed by the optic components 305 to a photoresist layer 318 disposed on a wafer 316 that is supported on the wafer stage 320. The computing system 710 can control generation of EUV radiation by the rotating target EUV radiation generation system 100 and control positioning of the wafer by controlling the wafer stage 320. After exposure, the photoresist layer 318 is developed to form a pattern of openings in the layer, as described above. The patterned photoresist layer can be used as a mask in subsequent processes such as wet or dry etching to extend patterns into one or more underlying layers.

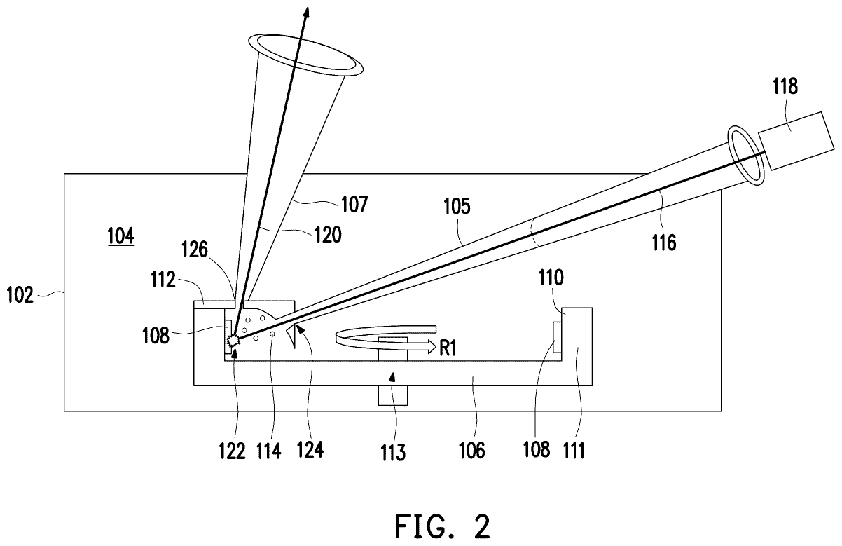

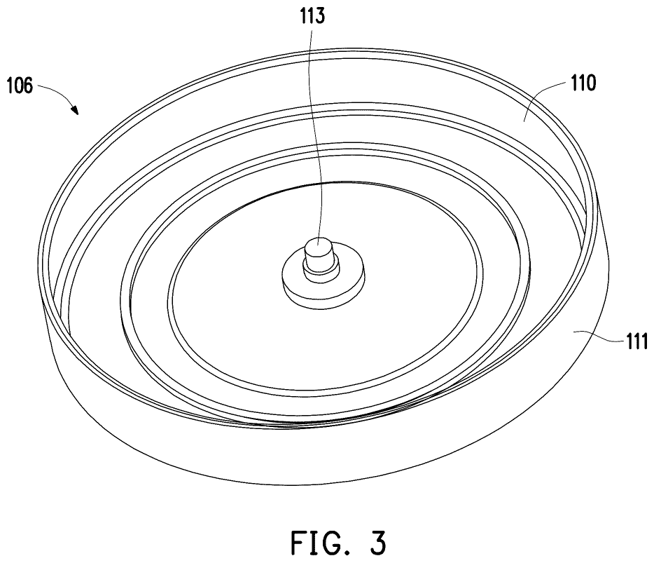

FIG. 2 is a schematic view of components of the rotating target EUV radiation generation system 100, in accordance with some embodiments. An EUV source vessel 102 includes a chamber 104 housing a crucible 106. A target material 108 is disposed on an inner peripheral surface 110 of a peripheral wall 111 of the crucible 106. The crucible 106 can be made of a metal, such as a stainless steel or a steel alloy. In some embodiments, the crucible 106 is made of metals that are dissimilar from the target material. In some embodiments, the crucible 106 rotates in direction R1 around an axis 113 during generation of EUV radiation. The direction of rotation can be clockwise or counter-clockwise. In some embodiments, a motor (not shown) is provided to rotate the crucible up to 25,000 rotations per minute (rpm). In some embodiments, the peripheral wall 111 is substantially circular in plan view. In some embodiments, the rotation of the crucible 110 is controlled by the computing system 710. FIG. 3 is a perspective view of the crucible 106 in accordance with an embodiment.

In some embodiments, the target metal 108 is deposited in a continuous band on the inner peripheral surface 110 of the peripheral wall 111. A catcher 112 is disposed in the chamber 104 and suspended above the crucible 106 so as to permit free rotation of the crucible while the catcher is stationary. In some embodiments, the catcher 112 is configured to collect debris 114 generated by irradiation of the target material 108 with a laser beam 116.

The laser beam 116 is emitted from a laser generator 118. In various embodiments, the laser generator can include a laser diode, a solid state laser such as a carbon dioxide (CO₂) laser source, or a neodymium-doped yttrium aluminum garnet (Nd: YAG) laser source. The laser generator 118 can be a substantially stationary laser and emit the laser beam 116 to superheat a target metal 108 disposed in the crucible 106, as the crucible is rotated at high speed. As the crucible is rotated, the target material passes through the laser's excitation zone. In various embodiments, the laser beam 116 is substantially continuous or pulsed.

In some embodiments, the target metal includes tin (Sn), a tin alloy such as a eutectic alloy containing Sn and lithium (Li), or any other useful metal. In some embodiments, the target material is liquified on the inner peripheral surface 110 of the peripheral wall 111 during operation of the apparatus 10. In some embodiments, the rotating target EUV radiation generation system includes a heater proximal to the crucible 106 to maintain the target material in liquid form. As the target material 108 on the wall 111 of the crucible rotates into the excitation zone of the laser beam 116, the energy from the laser beam can vaporize the target material into a high temperature plasma 122 that emits EUV radiation 120.

The EUV source vessel 102 includes a first channel 105 configured to permit ingress of the laser beam 116 into the chamber 104 and a second channel 107 configured to permit egress of the EUV radiation 120 from the chamber 104. In some embodiments, the first channel 105 and the second channel 107 are respectively coupled to the vessel 102 and in communication with the chamber 104. In some embodiments, the first channel 105 is connected to a first aperture 124 through the catcher 112, and the second channel 107 is connected to a second aperture 126 through the catcher 112. In some embodiments, the first aperture 124 permits ingress of the laser beam 124 to irradiate the target material 108 and the second aperture 126 permits egress of the EUV radiation 120 from the region of plasma generation. In some embodiments, the second aperture 126 of the catcher is disposed proximal to the first aperture 124. In some embodiments, the catcher includes a single aperture (not shown) permitting both ingress the laser beam and egress of the EUV radiation. In some embodiments, the chamber 104 is held in a vacuum state, such as a high-vacuum chamber state. In some embodiments, the chamber 104 has a round or oval shape in plan view.

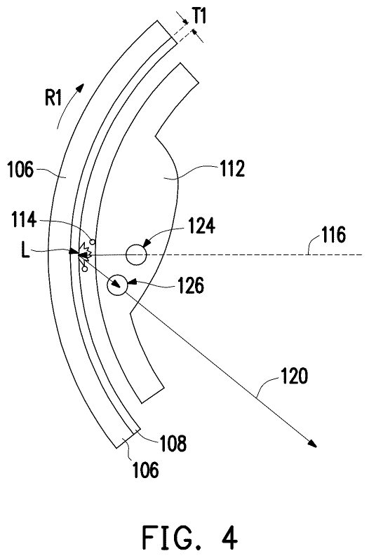

FIG. 4 is a schematic plan view of a portion of the rotating target EUV radiation generation system 100 showing a portion of the crucible 106 and the catcher 112, in accordance with some embodiments. Plasma is generated at point L by irradiation of the target material 108 with the laser beam 116 such that the plasma emits the EUV radiation 120. Generation of the plasma also produces the debris 114, such as ions, gases, atoms, and particles of the target material. In some embodiments, the debris 114 undesirably accumulates on various components of the rotating target EUV radiation generation system 100 such as the catcher 112 and the crucible 106. In some embodiments, the debris interferes with the irradiation of the target material 114 with the laser beam 116 and causes a fluctuation of intensity the generated EUV radiation. Debris accumulation can cause defocusing of the laser light on the target material. For example, where the size of a laser spot of the laser beam on the target material is set to approximately 30 micrometers (μm) in diameter, an amount of defocusing caused by debris on the crucible 106 can be approximately 3 μm, and the size of the laser spot instead becomes 33 μm. As a result, the laser spot volume expands, and if the laser power is not adjusted to compensate, the intensity of the generated EUV radiation can decrease. Fluctuations in consistency of generated EUV radiation can cause problems when using the radiation to inspect masks or perform lithography processes.

In some embodiments, the catcher 112 is configured to collect debris 114. In some embodiments, the catcher 112 is disposed proximal to the target material layer 108 and the crucible 106. In some embodiments, the target material layer 108 is disposed between the catcher 112 and the crucible 106. In some embodiments, the location L where the plasma 112 is generated is disposed between the target material layer 108 and the catcher 112. In some embodiments, the catcher 122 catches the debris 114 generated at the location L. In some embodiments, the catcher 112 is spaced apart from target material layer 108. In some embodiments, the debris 114 collected by the catcher 112 circulates within a portion of the crucible 106 facing the catcher. In some embodiments, the catcher 112 is disposed over at least a portion of the target material layer 108 in plan view. Structures of the catcher 112 and associated components of the rotating target EUV radiation generation system 100 can be adjusted according to configurations of the target material layer 108 and the crucible 106.

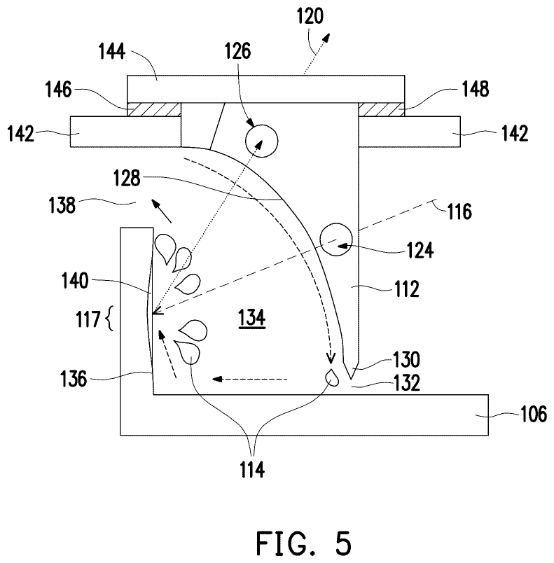

FIG. 5 is a cross-sectional view of portions of the catcher 112 and the crucible 106 according to some embodiments. The catcher 112 includes the first aperture 124 permitting ingress of the laser beam 116 and the second aperture 126 permitting egress of the EUV radiation 120. The EUV radiation 120 and debris 114 are generated upon irradiation of the liquified target material 140 within the target region 117 using the laser beam 116. The catcher 112 includes a debris catching surface 128 including an arcuate or concave cross-section that faces the target material 140. The end portion 130 of the debris catching surface 128 of the catcher 112 forms a debris return 132 between the catcher and the crucible 106. Debris 114 can fall from the end portion 130 of the catcher 112, into the debris return 132, onto the floor of the crucible 106. In some embodiments, a sidewall 136 of the crucible 106 and the debris catching surface 128 of the catcher 112 form a hollow interior region 134 in which the debris can circulate (circulation schematically illustrated by the dashed arrows). In some embodiments, centrifugal force imparted by rotation of the crucible 106 moves the debris 114 in the direction of the dashed arrows from the debris return 132, around the hollow interior region 134, and toward an outlet 138. In some embodiments, centrifugal force returns the debris 114 to the target region 117 on an inner surface of the sidewall 136, and the returned debris is irradiated with the laser beam 116 to generate the plasma and EUV radiation 120.

In some embodiments, the catcher 112 is supported above the crucible 106 by a frame 142. In some embodiments, the catcher 112 is disposed through an opening formed through the frame 142. In some embodiments, the frame 142 is supported by one or more support structure (not shown) of the vessel 102 housing the crucible 106. In some embodiments, the frame 142 extends across the cavity of the crucible 112 from one edge of the sidewall 136 to an opposite edge of the sidewall (not shown). The frame 142 supports the catcher 112 so that the crucible 106 can rotate while the catcher is stationary. In some embodiments, a shield 144 is disposed over the catcher 112 and portions of the frame 142. In some embodiments, one or more shims 146, 148 are disposed in gaps between the frame 142 and the shield 144. In some embodiments, the shims 146, 148 contact the frame 142, the catcher 112, and the shield 144. In some embodiments, the frame 142 and/or the shield 144 extend from one peripheral edge of the crucible 106 to an opposite peripheral edge (not shown) of the crucible.

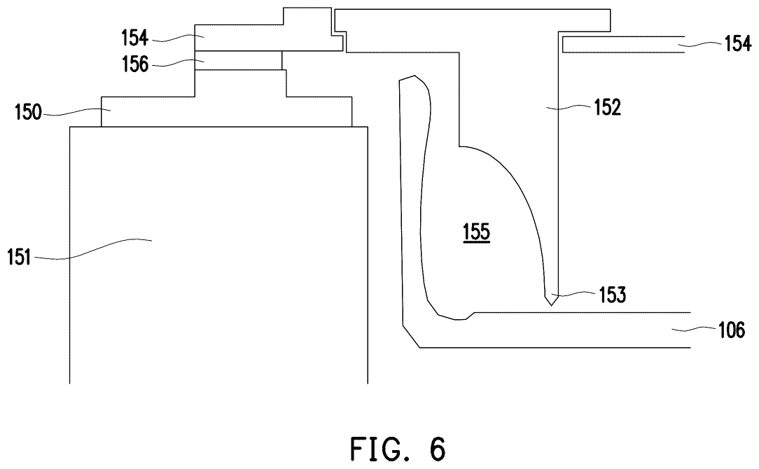

FIG. 6 schematically illustrates a cross-sectional view of an alternative embodiment of a structural engagement between a frame 150, a catcher 152, and a shield 154. A shim 156 resides in a space between the shield 154 and the frame 150. One peripheral edge of the crucible 106 is shown under the catcher 152. The frame 150 and shim 156 have ring structures that surround the periphery of the crucible 106. The frame 150 rests on a support 151 of the vessel 102. The shield 154 covers the cavity of the crucible 106 and the catcher 152 is supported within an opening in the shield 154. The shield 154 extends from over one peripheral edge of the crucible 106 to an opposite peripheral edge (not shown) of the crucible.

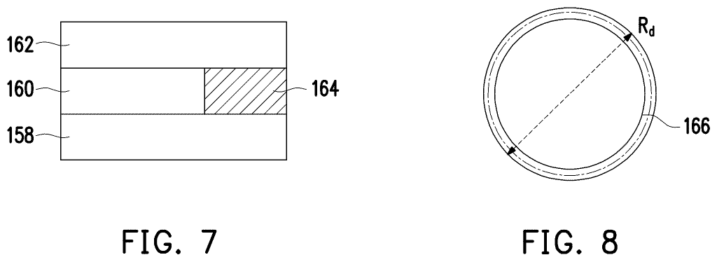

FIG. 7 schematically illustrates a partial cross-sectional view of yet another alternative embodiment of structural engagement between a portion of a frame 158, a portion of a catcher 160, and a portion of a shield 162 for suspending the catcher above the crucible. A shim 164 is disposed in a gap proximal to the catcher 160 and between the shield 162 and the frame 158, in some embodiments. The shim 164 contacts the catcher 160, the frame 158, and the shield 162.

FIG. 8 schematically illustrates a plan view of an embodiment of a shim 166 that can be used with the embodiments shown in FIGS. 5, 6, and 7. The shim 166 has a ring shape with an outer diameter R_{d}. In some embodiments, the outer diameter R_{d} ranges from about 150 mm to about 300 mm, from about 180 mm to about 250 mm, or from about 200 mm to about 220 mm. The shim is not limited to a ring structure in plan view and can include any useful structure such as oval, rectangular, or any irregular structure conforming to one or more other components such as the vessel, the frame, the catcher, and the shield. The shim can have any useful dimensions suitable for interfacing with one or more of the vessel, the frame, the catcher, and the shield. Moreover, two or more shims of different dimensions (e.g., diameters) can be used with the frame, the catcher, and the shield, as illustrated in connection with the embodiment of the shims 146, 148 shown in FIG. 5.

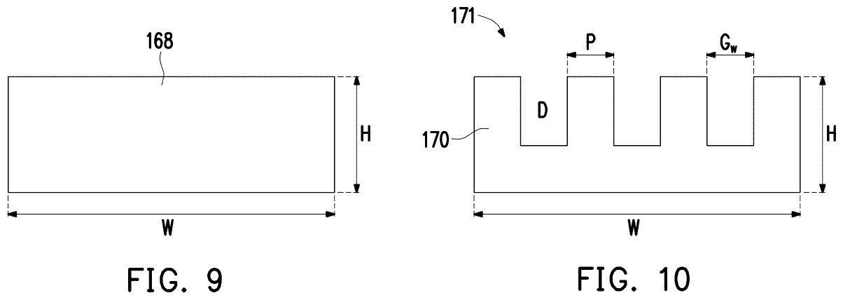

FIGS. 9 and 10 schematically illustrate cross-sections of portions of shims 168 and 170 having different structural configurations, according to some embodiments. The shims 168 and 170 can be ring structured or have any other useful structure. The shim 168 shown in FIG. 9 includes flat surfaces while the shim 170 shown in FIG. 10 includes three flat surfaces and one grooved surface 171. The height (H) of the shims 168, 170 can range from about 0.2 mm to about 10 mm, from about 1 mm to about 8 mm, or from about 3 mm to about 6 mm in some embodiments. The width (W) of the shims 168, 170 can range from about 1 mm to about 30 mm, from about 5 mm to about 20 mm, or from about 10 mm to about 15 mm in some embodiments. In some embodiments, the circumference of (C) of the shims 168, 170 can be 2πR_{d}, where π represents pi and R_{d} represents the outer diameter of the shim. In some embodiments, the outer diameter R_{d} of the shims 168, 178 corresponds to ranges discussed in connection with R_{d} of the embodiment shown in FIG. 8. In some embodiments, a groove depth (D) of the shim 170 is greater than about 0.1 mm or ranges from about 0.2 mm to about 8 mm, or from about 1 mm to about 5 mm. In some embodiments, a groove pitch (P) of the shim 170 ranges from about 1 mm to about 10 mm, or from about 3 mm to about 7 mm. In some embodiments, a groove width (G_{w}) of the shim 170 ranges from more than about 0 mm to about 2 mm, or from about 1 mm to about 1.5 mm. In some embodiments the grooves have rectangular cross-sectional structure as shown in the cross-sectional view of FIG. 10. In some embodiments, grooves have rounded (U-shaped) bottoms in a cross-sectional view (not shown).

In some embodiments, one or more shims are provided to improve thermal conduction between one or more components of the rotating target EUV radiation generation system such as the frame, the shield, the catcher, and the vessel. In some embodiments, the shim includes one or more materials exhibiting high thermal conductivity and stability at high operating temperatures. A shim can enhance thermal dissipation and conductivity between any two or more components such as the frame, shield, catcher, and vessel, thereby improving temperature control of the EUV generation process conducted in the chamber. In some embodiments, one or more shims help maintain temperatures of a catcher below 350° C. By improving the thermal conduction, one or more shims can improve heat transfer away from a region where EUV radiation is generated and reduce the operating temperature of the rotating target EUV radiation generation system. In some embodiments, a shim is formed of one or more of copper, aluminum, aluminum alloys, graphite, tungsten, molybdenum, and silicon carbide.

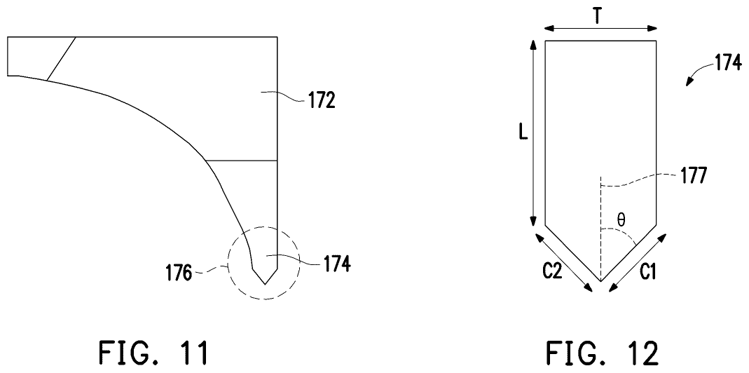

FIG. 11 schematically illustrates a cross-section of a portion of a catcher 172 including an end portion 174 according to some embodiments. FIG. 12 schematically illustrates an enlarged view of the section of the end portion 174 within the annotated circle 176 in FIG. 11. In some embodiments, the end portion 130, 153, as shown in FIGS. 5 and 6, faces the floor of the cavity of the crucible 106. In some embodiments, the structure of the end portion 174 of the catcher 172 facilitates the circulation of liquified target material debris 114 within the hollow interior region 134, 155 shown in FIGS. 5 and 6 such that the liquified debris 114 returns to the target region 117. In some embodiments, the faces C1 and C2 of the end portion 174 form a V-structure to facilitate the liquid debris 114 quickly dropping from the catcher 112 into the debris return 132 shown in FIG. 5.

The length (L) of the uncurved wall section of the end portion 174 of the catcher shown in FIG. 12 ranges from about 20 mm to about 50 mm, from about 25 mm to about 45 mm, or from about 30 mm to about 40 mm in some embodiments. The end faces C1 and C2 each form an angle theta (Θ) from a center line 177 of the uncurved wall section of the end portion 174. The angle theta (Θ) ranges from about 40 degrees to about 50 degrees, from about 43 degrees to about 47 degrees, or is about 45 degrees in some embodiments. The lengths of the end faces C1 and C2 each range from about 2 mm to about 10 mm, from about 3 mm to about 8 mm, or about from about 4 mm to about 6 mm according to some embodiments. In some embodiments, the lengths of the end faces C1 and C2 are identical such that the end faces C1 and C2 of the end portion 174 are symmetrical. In some embodiments, the lengths of the end faces C1 and C2 are different. In some embodiments, the thickness (T) of the uncurved wall section of the end portion 174 is less than the length (L) of the uncurved wall section but greater than the lengths of the end faces C1 and C2. In some embodiments, a ratio (T/C) of the thickness (T) to the length (C) of either of the end faces C1 and C2 is about the square root of two (√2). The structure and dimensions of the end portion 174 and the uncurved wall section provide improved liquid debris circulation within the crucible, particularly in the region between the peripheral wall of the crucible and the arcuate or concave surface of the catcher. The shape, angle, and dimensions of parts of the end portion including the uncurved wall section can be tailored so that the V-structure provided by the end faces helps prevent the accumulation of debris and facilitates the rapid dropping off of debris from the end portion.

In some embodiments, the debris catching surface of the catcher can include a material exhibiting a high water contact angle wettability (hydrophobicity) such that the liquified debris (e.g., liquid tin debris) readily runs across the debris catching surface to the debris return without substantially accumulating on the debris catching surface. The high water contact angle facilitates the rapid removal of the liquid debris from surfaces of the catcher, which can prevent substantial accumulation of the target material debris and improve circulating efficiency of debris within a region bounded by the catcher and the crucible. The high circulation efficiency can facilitate the return of the liquified debris to the target region and to the outlet of the region bounded by the catcher and the crucible. In some embodiments, the debris catching surface includes a coating including the material exhibiting the high water contact angle (hydrophobicity). In some embodiments, the catcher is formed of a material exhibiting the high water contact angle (hydrophobicity).

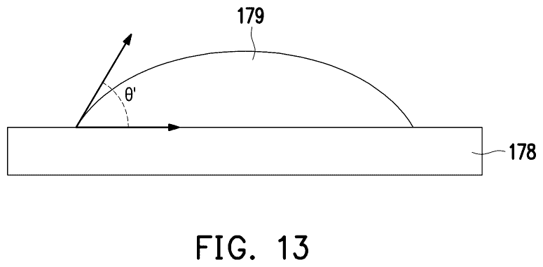

FIG. 13 schematically illustrates a portion of a material 178 forming either a coating on the debris catching surface of the catcher, or forming the catcher. A water droplet 179 rests on the material 178 and exhibits a contact angle theta (Θ) . In some embodiments, the high water contact angle (hydrophobicity) corresponds to the material of the catcher or the coating formed on the debris catching surface exhibiting a water contact angle theta (Θ) of greater than or equal to about 80°, greater than or equal to about 85°, or greater than or equal to about 90°. In some embodiments, the contact angle of a clean sample of the material of the catcher or the coating formed on the debris catching surface can be measured using a goniometer, such as an Ossila L2004A Contact Angle Goniometer. Instructions for the use of an Ossila L2004A are provided in the Contact Angle Goniometer User Manual, Manual Version 1.2.E, Ossila Limited, 2023, which are incorporated herein by reference in their entirety.

Tungsten, tungsten alloys, and tungsten compounds are useful forming the coating on the debris catching surface of the catcher or form the catcher because the materials exhibit high water contact angle (hydrophobicity). Tungsten, tungsten alloys, and tungsten compounds have a property of attenuating the accumulation of debris (such as tin droplets) on the surface of the catcher. The high melting points and resistance to corrosion exhibited by tungsten, tungsten alloys, and tungsten compounds also make the materials resistant to deformation and degradation under high-temperature and oxidizing conditions in the rotating target EUV radiation generation system. A catcher or coating provided thereon can be formed of pure tungsten, a tungsten alloy, or a tungsten compounds such as one or more of tungsten nitride, tungsten carbide, tungsten disulfide, and tungsten oxide. Additional materials that exhibit high water contact angle (hydrophobicity) that are useful for forming a catcher or a coating on a debris catching surface include one or more of tantalum, iridium, ruthenium, osmium, and rhenium. Tantalum, iridium, ruthenium, osmium, and rhenium can also be used in combination with one or more of tungsten, a tungsten alloy, or a tungsten compound. The high surface energy and wettability of tungsten, tantalum, iridium, ruthenium, osmium, and rhenium make the materials a suitable choice for applications that require not only high surface energy and wettability but also thermal stability, corrosion resistance, and mechanical strength.

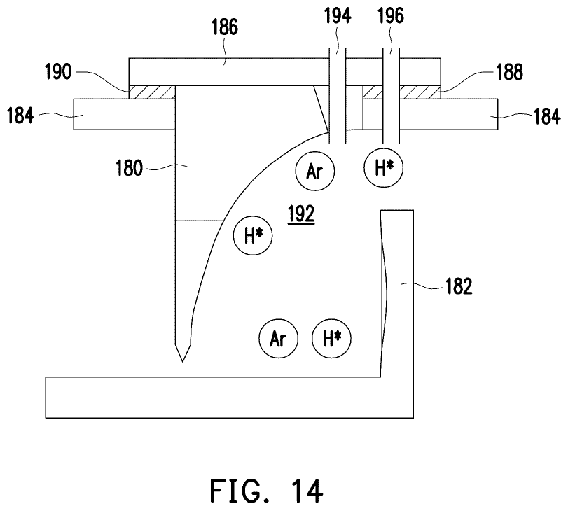

FIG. 14 schematically illustrates a cross-section of a catcher 180 disposed over a portion of a crucible 182 according to some embodiments. The catcher is supported by a frame 184. A shield 186 is disposed over the catcher 180, and shims 188, 190 are disposed in gaps between the shield 186 and the frame 184. A gas is present in a hollow interior region 192 bounded by the catcher 180 and the crucible 182. The gas can be introduced through an inlet 194 and extracted through an outlet 196. The gas can include hydrogen gas (H₂) alone, or a combination of hydrogen gas with one or more inert gases such as a nitrogen (N₂), argon (Ar), and helium (He). Upon heating, the hydrogen gas forms hydrogen radicals (H*) that attenuate oxidation of surfaces inside the chamber, such as surfaces of the catcher 180 and the crucible 182. The hydrogen radicals can mitigate the oxidation by reacting with oxygen that is otherwise present in the chamber, thus reducing the amount of oxygen available for oxidation. The hydrogen radicals can also serve to maintain the hydrophobic properties of components such as a coating formed on the catcher or a material forming the catcher.

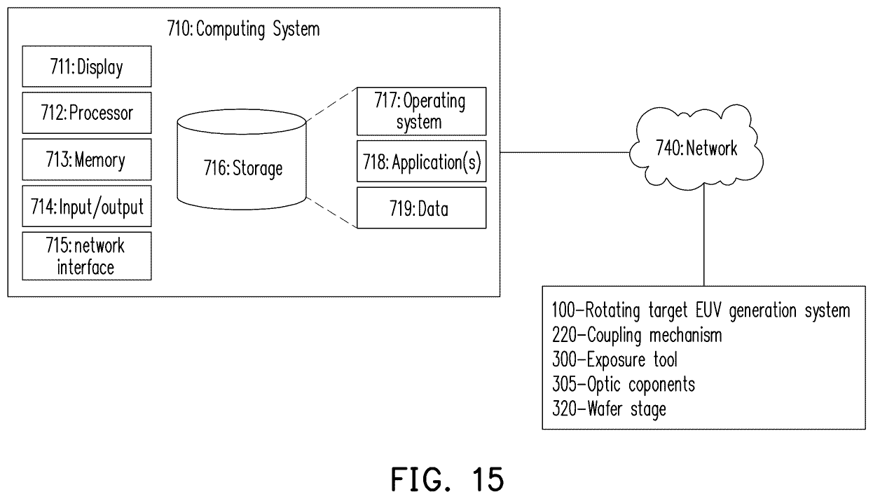

In some embodiments, the computing system 710 can be programmed to operate one or more of components of the EUV inspection system 10 or the EUV lithography system 15 to perform any method provided in the present disclosure. A computing system 710 can include any one or more of a local computing device, one or more controllers connected to the EUV inspection system 10 or the EUV lithography system 15, or a network of computing devices. In an embodiment, the computing system 710 is programmed to conduct operations including controlling one or more of the rotating target EUV radiation generation system 100, the exposure tool 300, the inspection sensor 315, or the wafer stage 320. The computing system 710 can also process one or more images captured by the inspection sensor 315 to determine whether the mask includes any defects, damage, or contamination. FIG. 15 illustrates an embodiment of the computing system 710 communicably connected to one or more of the rotating target EUV radiation generation system 100, the exposure tool 300, the inspection sensor 315, or the wafer stage 320 using a wireless or wired network 740 to permit data exchange therebetween. In some embodiments, the computing system 710 is implemented using hardware or a combination of software and hardware, either in a dedicated server, integrated into another entity, or distributed across multiple entities such as via a cloud or wired network.

The computing system 710 includes a display 711, a processor 712, a memory 713, an input/output interface 714, a network interface 715, and storage 716 storing an operating system 717, programs or applications 718 such as applications for controlling one or more of the rotating target EUV radiation generation system 100, the exposure tool 300, the inspection sensor 315, or the wafer stage 320. The processor 712 can be a general-purpose microprocessor, a microcontroller, or the like. The storage 716 can be a random access memory (RAM), a flash memory, a read-only memory (ROM), a hard or optical disk, or any other suitable storage device, for storing information and instructions to be executed by processor 712. The processor 712 and storage 716 can be supplemented by or incorporated in special purpose logic circuitry.

The network interface 715 can include networking interface cards, such as Ethernet cards and modems. In some embodiments, the input/output interface 714 is configured to connect to a plurality of devices, such as an input device and/or an output device. Example input devices include a keyboard and a pointing device, e.g., a mouse or a trackball, by which a user can provide input to the computing system 710. Example output devices include display devices, such as LED (light emitting diode) or LCD (liquid crystal display) screens for displaying information to the user.

The applications 718 can include instructions which, when executed by the computing system 710 (or a processor 712 thereof), causes the computing system 710 (or the processor 712 thereof) to control one or more of the rotating target EUV radiation generation system 100, the exposure tool 300, the inspection sensor 315, or the wafer stage 320, and perform other operations, methods, and/or processes that are explicitly or implicitly described in the present disclosure.

The data 719 can include data including parameters used in the control operations, data that is received, for example, through the input/output interface 714 or through the network interface 715 transmitted from the rotating target EUV radiation generation system 100, the exposure tool 300, the inspection sensor 315, and/or the wafer stage 320, data for displaying on the display 711, data that is transmitted to or from the rotating target EUV radiation generation system 100, the exposure tool 300, the inspection sensor 315, and/or the wafer stage 320 via the network 740, or data generated during operation of the computing system 710.

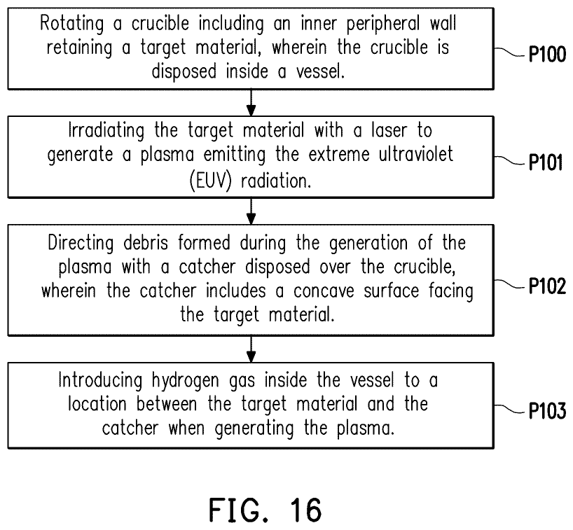

FIG. 16 illustrates a flow chart of a method of generating extreme ultraviolet (EUV) radiation according to some embodiments. The method includes an operation P100 of rotating a crucible including an inner peripheral wall retaining a target material, wherein the crucible is disposed inside a vessel. The method further includes an operation P101 of irradiating the target material with a laser to generate a plasma emitting the EUV radiation. The method further includes an operation P102 of directing debris formed during the generation of the plasma with a catcher disposed over the crucible. In some embodiments, the method further includes an operation P103 of introducing hydrogen gas inside the vessel to a location between the target material and the catcher when generating the plasma.

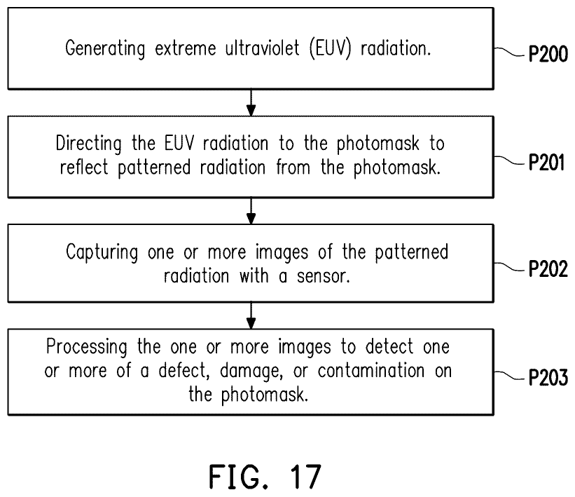

FIG. 17 illustrates a flow chart of a method of inspecting a photomask according to some embodiments. The method includes an operation P200 of generating extreme ultraviolet (EUV) radiation. In some embodiments, the operation P200 is conducted according to the method shown in FIG. 16. The method in FIG. 17 further includes an operation P201 of directing the EUV radiation to the photomask to reflect patterned radiation from the photomask. The method further includes an operation P202 of capturing one or more images of the patterned radiation with a sensor. The method further includes an operation P203 of processing the one or more images to detect one or more of a defect, damage, or contamination on the photomask.

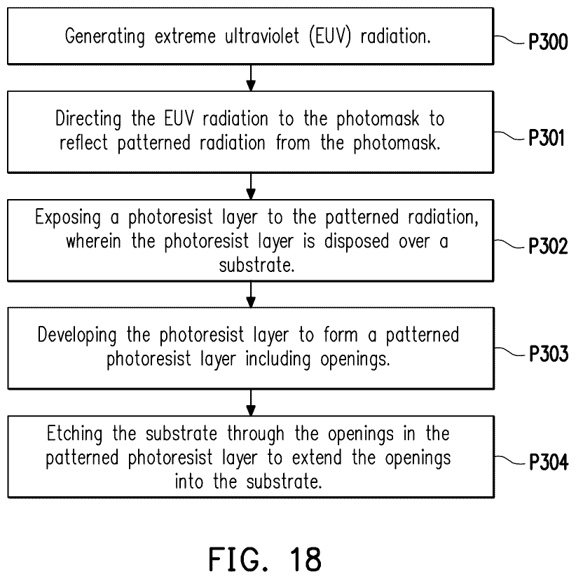

FIG. 18 illustrates a flow chart of a method of manufacturing a semiconductor device according to some embodiments. The method includes an operation P300 of generating extreme ultraviolet (EUV) radiation. In some embodiments, the operation P300 is conducted according to the method shown in FIG. 16. The method in FIG. 18 further includes an operation P301 of directing the EUV radiation to a photomask to reflect patterned radiation from the photomask. The method further includes an operation P302 of exposing a photoresist layer to the patterned radiation, wherein the photoresist layer is disposed over a substrate. The method further includes an operation P303 of developing the photoresist layer to form a patterned photoresist layer including openings, and an operation P304 of etching the substrate through the openings in the patterned photoresist layer to extend the openings into the substrate. In some embodiments, the substrate includes a plurality of layers, and the etching extends the openings into at least one of the plurality of layers.

The present disclosure provides structures, materials, and methods for maintaining the stability of EUV radiation produced by a rotating target EUV radiation generation system. By maintaining the stability of the EUV radiation, the stability and integrity of associated lithography and inspection processes can also be maintained.

According to an embodiment, a debris catcher includes a concave surface configured to face a target material of a rotating target extreme ultraviolet (EUV) radiation generation system, wherein the concave surface exhibits a water contact angle (Θ) of greater than 85°. In an embodiment, the concave surface is covered with a coating exhibiting the water contact angle (Θ) of greater than 85°. In an embodiment, the coating includes tungsten. In an embodiment, the coating includes a tungsten compound. In an embodiment, the debris catcher is formed of a material exhibiting the water contact angle (Θ) of greater than 85°. In an embodiment, the material includes tungsten. In an embodiment, the material includes a tungsten compound. In an embodiment, the debris catcher further includes an end portion configured to be disposed proximal to a floor of a crucible of the rotating target EUV radiation generation system, wherein the end portion has opposing faces forming a symmetrical V-structure configured to face floor of the crucible.

According to another embodiment, a rotating target extreme ultraviolet (EUV) radiation generation system includes a vessel forming a chamber; a crucible disposed in the chamber, the crucible including a cavity and a peripheral wall surrounding the cavity, and the crucible configured to rotate about an axis at a center of the cavity; a catcher disposed over the cavity of the crucible, the catcher including a concave surface facing a portion of an interior surface of the peripheral wall of the crucible; a frame suspending the catcher over the crucible; a shield disposed over the frame; and a shim including a thermally conductive material disposed in a gap between the frame and the shield. In an embodiment, the thermally conductive material includes copper. In an embodiment, the catcher is disposed through an opening in the frame, the shield covers a side of the catcher opposite the crucible, and the shim is disposed between an edge of the shield and the frame. In an embodiment, the shim contacts the frame, the shield, and the catcher. In an embodiment, the shim fills a gap formed by the frame, the shield, and the catcher. In an embodiment, the catcher is disposed through an opening in the shield, and the shim is disposed between an edge of the shield and the frame. In an embodiment, the shim includes a grooved surface.

According to another embodiment, a method of generating extreme ultraviolet (EUV) radiation includes rotating a crucible including an inner peripheral wall retaining a target material, wherein the crucible is disposed inside a vessel; irradiating the target material with a laser to generate a plasma emitting the EUV radiation; and directing debris formed during the generation of the plasma with a catcher disposed over the crucible. In an embodiment, the catcher includes a concave surface facing the target material, and the concave surface exhibits a water contact angle (Θ) of greater than 85°. In an embodiment, the concave surface is covered with a coating exhibiting the water contact angle (Θ) of greater than 85°. In an embodiment, the catcher is formed of a material exhibiting the water contact angle (Θ) of greater than 85°. In an embodiment, the concave surface includes tungsten. In an embodiment, the method further includes introducing hydrogen gas inside the vessel to a location between the target material and the catcher when generating the plasma.

According to another embodiment, a method of inspecting a photomask includes generating extreme ultraviolet (EUV) radiation through a method including rotating a crucible including an inner peripheral wall retaining a target material, irradiating the target material with a laser to generate a plasma emitting the EUV radiation, and directing debris formed during the generation of the plasma with a catcher disposed over the crucible. In an embodiment, the catcher includes a concave surface facing the target material, and the concave surface exhibits a water contact angle (Θ) of greater than 85°. The method further includes directing the EUV radiation to the photomask to reflect patterned radiation from the photomask; capturing one or more images of the patterned radiation with a sensor; and processing the one or more images to detect one or more of a defect, damage, or contamination on the photomask. In an embodiment, the concave surface is covered with a coating exhibiting the water contact angle (Θ) of greater than 85°. In an embodiment, the catcher includes a material exhibiting the water contact angle (Θ) of greater than 85°. In an embodiment, the concave surface includes tungsten.

According to another embodiment, a method of manufacturing a semiconductor device includes generating extreme ultraviolet (EUV) radiation through a method including rotating a crucible including an inner peripheral wall retaining a target material, irradiating the target material with a laser to generate a plasma emitting the EUV radiation, and directing debris formed during the generation of the plasma with a catcher disposed over the crucible, wherein the catcher includes a concave surface facing the target material, and the concave surface exhibits a water contact angle (Θ) of greater than 85°. The method further includes directing the EUV radiation to a photomask to reflect patterned radiation from the photomask, exposing a photoresist layer to the patterned radiation, wherein the photoresist layer is disposed over a substrate; developing the photoresist layer to form a patterned photoresist layer including openings; and etching the substrate through the openings in the patterned photoresist layer to extend the openings into the substrate. In an embodiment, the concave surface is covered with a coating exhibiting the water contact angle (Θ) of greater than 85°. In an embodiment, the catcher is formed of a material exhibiting the water contact angle (Θ) of greater than 85°. In an embodiment, the concave surface includes tungsten. In an embodiment, the substrate includes a plurality of layers, and the etching extends the openings into at least one of the plurality of layers.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A debris catcher comprising:
an concave surface configured to face a target material of a rotating target extreme ultraviolet (EUV) radiation generation system, wherein the concave surface exhibits a water contact angle (Θ) of greater than 85°.

2. The debris catcher of claim 1, wherein the concave surface is covered with a coating exhibiting the water contact angle (Θ) of greater than 85°.

3. The debris catcher of claim 2, wherein the coating comprises tungsten.

4. The debris catcher of claim 3, wherein the coating comprises a tungsten compound.

5. The debris catcher of claim 1, wherein the debris catcher is formed of a material exhibiting the water contact angle (Θ) of greater than 85°.

6. The debris catcher of claim 5, wherein the material comprises tungsten.

7. The debris catcher of claim 6, wherein the material comprises a tungsten compound.

8. The debris catcher of claim 1, further comprising an end portion configured to be disposed proximal to a floor of a crucible of the rotating target EUV radiation generation system, wherein the end portion has opposing faces forming a symmetrical V-structure configured to face floor of the crucible.

9. A rotating target extreme ultraviolet (EUV) radiation generation system comprising:
a vessel forming a chamber;
a crucible disposed in the chamber, the crucible including a cavity and a peripheral wall surrounding the cavity, and the crucible configured to rotate about an axis at a center of the cavity;
a catcher disposed over the cavity of the crucible, the catcher including a concave surface facing a portion of an interior surface of the peripheral wall of the crucible;
a frame suspending the catcher over the crucible;
a shield disposed over the frame; and
a shim comprising a thermally conductive material disposed in a gap between the frame and the shield.

10. The rotating target EUV radiation generation system of claim 9, wherein the thermally conductive material comprises copper.

11. The rotating target EUV radiation generation system of claim 9, wherein the catcher is disposed through an opening in the frame, the shield covers a side of the catcher opposite the crucible, and the shim is disposed between an edge of the shield and the frame.

12. The rotating target EUV radiation generation system of claim 11, wherein the shim contacts the frame, the shield, and the catcher.

13. The rotating target EUV radiation generation system of claim 12, wherein the shim fills a gap formed by the frame, the shield, and the catcher.

14. The rotating target EUV radiation generation system of claim 9, wherein the catcher is disposed through an opening in the shield, and the shim is disposed between an edge of the shield and the frame.

15. The rotating target EUV radiation generation system of claim 14, wherein the shim includes a grooved surface.

16. A method of generating extreme ultraviolet (EUV) radiation comprising:
rotating a crucible including an inner peripheral wall retaining a target material, wherein the crucible is disposed inside a vessel;
irradiating the target material with a laser to generate a plasma emitting the EUV radiation; and
directing debris formed during the generation of the plasma with a catcher disposed over the crucible, wherein the catcher includes a concave surface facing the target material, and the concave surface exhibits a water contact angle (Θ) of greater than 85°.

17. The method of claim 16, wherein the concave surface is covered with a coating exhibiting the water contact angle (Θ) of greater than 85°.

18. The method of claim 16, wherein the catcher is formed of a material exhibiting the water contact angle (Θ) of greater than 85°.

19. The method of claim 16, wherein the concave surface comprises tungsten.

20. The method of claim 16, further comprising introducing hydrogen gas inside the vessel to a location between the target material and the catcher when generating the plasma.
